(19) United States
(12) Patent Application Publication
(10) Pub. No.: US 2008/0179726 A1
(43) Pub. Date: Jul. 31, 2008

(54) Multi-chip semiconductor package and method for fabricating the same

(75) Inventors: Chien-Chih Sung, Taichung (TW); Chung-Pao Wang, Taichung (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/011,833

(22) Filed: Jan. 29, 2008

(30) Foreign Application Priority Data
Jan. 31, 2007 (TW) 096103467

(51) Int. Cl. H01L 23/02; H01L 21/00

(52) U.S. Cl. 257/685; 438/107; 257/E23.085

(57) ABSTRACT

A multi-chip semiconductor package and a method for fabricating the same are disclosed. The method includes electrically connecting a first chip mounted onto a substrate with the substrate through a plurality of first bonding wires; applying an adhesive layer on the substrate at a position proximate to the first chip in a horizontal direction, wherein the adhesive layer at least covers a portion of wireloop of each of the first bonding wires and a first bonding region bonded thereto, such that a second chip overlaps the first bonding region to reduce space wasted on the substrate, thereby allowing more and larger-sized chips to be attached thereon.

### FIELD OF THE INVENTION

The present invention relates to multi-chip semiconductor packages and methods for fabricating the same, and more particularly, to a semiconductor package with more than two chips disposed on a substrate and separated horizontally from each other, and a method for fabricating the same.

### BACKGROUND OF THE INVENTION

Because the tendency of slim and miniaturized portable electronic products for use in communication, the Internet and computers become increasingly important, the electronic products are developed to be multi-functional and with high performance to satisfy the ever-lasting demand for integration and miniaturization of packages. Ability and capacity of a single semiconductor package is increased to meet the tendency of small-sized, large capacity and high-speed electronic products, and are embodied as “multi-chip module” (MCM) in prior art. Semiconductor packages having MCM mount at least two chips on a substrate (such as substrates or lead frames) having a single package, and the chip and the substrate could be mounted in two ways briefly described in FIGS. 1 to 3.

FIG. 1 is a schematic diagram showing a multi-chip semiconductor package with chips separated in a horizontal direction in prior art. As depicted in FIG. 1, the semiconductor package comprises: a substrate 100 having a core layer 100c, a solder mask layer 100a on a top surface of the core layer 100c and another solder mask layer 100b on a bottom surface of the core layer 100c; a first chip 110 having an active surface 110a and a non-active surface 110b, wherein the non-active surface 110b is attached to the solder mask layer 100a of the substrate 100, and the active surface 110a is electrically connected to a first bonding region 130 on the top surface of the substrate 100 through a plurality of first bonding wires 120; a second chip 140 having an active surface 140a and a non-active surface 140b, wherein the non-active surface 140b is attached to the solder mask layer 100a of the substrate 100 and separated from the first bonding region 130 by a certain interval, and the active surface 140a is electrically connected to a second bonding region 160 on the top surface of the substrate 100 through a plurality of second bonding wires 150; an encapsulant 170 for encapsulating the chips 110 and 140 separated by certain intervals; and a plurality of solder balls 180 mounted onto solder pads 181 on the bottom solder mask layer 100b of the substrate 100, so as to serve as external electrical contacts of the package.

One of the shortcomings of the above-mentioned multi-chip semiconductor packages is that the chips have to be separated from each other at a certain interval and the wire bonding regions have to set far away from each other to mount each of the chips, so that each of the wire bonding regions have an independent area, in order to prevent improper electrical connections among the bonding wires and chips. Accordingly, if a plurality of chips are to be accommodated on the substrate, a large die attachment region is needed for receiving these chips, thereby increasing the fabrication cost and making such invention difficult to meet demands of fabricating a slimmer and miniaturized electronic product. Referring to FIG. 2, a semiconductor package disclosed by U.S. Pat. No. 5,793,108 is shown, wherein each of the chips are stacked vertically on a substrate to accommodate more chips in the package. As depicted in FIG. 2, a first chip 210 is mounted onto a substrate 200, and then a second chip 220 is mounted onto the first chip 210, wherein the first and second chips 210, 220 are respectively electrically connected to the substrate 200 through a plurality of first bonding wires 230 and a plurality of second bonding wires 240. However, in order to prevent the second bonding wires 240 and the second chip 220 bonded thereto from adversely interfering with the first bonding wires 230 and the first chip 210, the size of the second chip 220 must be smaller than that of the first chip 210. Accordingly, the above-mentioned invention is incapable of stacking a plurality of chips having same size and functionality in the semiconductor package.

Referring to FIG. 3, a semiconductor package structure disclosed in the U.S. Pat. No. 6,900,528 entitled “Stacked Mass Storage Flash Memory Package” is illustrated to address the problem of affected densification of packages caused by size limits of the chips of the above-mentioned semiconductor packages. First, as shown in FIG. 3, a first chip 310 of the semiconductor package is mounted onto a substrate 300, and the first chip 310 is electrically connected to the substrate 300 through a plurality of first bonding wires 320. Then, a second chip 330 is mounted onto the first chip 310 in an offset manner, such that a portion of the second chip 330 is mounted onto the first chip 310. Lastly, the second chip 330 is electrically connected to the first chip 310 and the substrate 300 through a plurality of second bonding wires 340. Although the above-mentioned stacking method could resolve the problem of stacking chips with the same size, the problem of increased thickness caused by stacking arises. To resolve the new problem, the bottom S/M (solder mask) layer of the chip needs to be ground, in an attempt to lower the overall thickness of the entire package. However, such a process is time-consuming and expensive.

Accordingly, it is necessary to develop a multi-chip package that can effectively integrate more or larger chips in the package to increase electrical performance, and to avoid the problem of an increased overall height after packaging by stacking.

### SUMMARY OF THE INVENTION

In light of the drawbacks of the above prior arts, it is an object of the invention to provide a multi-chip semiconductor package and a method for fabricating the same, to integrate more and larger chips in a semiconductor package, so as to improve its efficiency and performance.

It is another object of the invention to provide a multi-chip semiconductor package and a method for fabricating the same, which can effectively integrate more and larger chips in a semiconductor package, without being constrained by the area of the packaging structure.

It is a further object of the invention to provide a multi-chip semiconductor package and a method for fabricating the same, which can avoid the problems of increased overall thickness of the semiconductor package caused by stacking to meet the demands for miniaturization of electronic products.

In order to attain the above and other objects, the invention discloses multi-chip semiconductor package, comprising: a substrate; a first chip having an active surface and a non-active surface opposed to the active surface, wherein the first chip is mounted onto the substrate through its non-active surface; a plurality of first bonding wires with one end thereof bonded to the active surface of the first chip and the other end bonded to a first bonding region on the substrate; at least a second chip having an active surface and a non-active surface opposed to the active surface, wherein the second chip is mounted to the substrate at a position proximate to the first chip in a horizontal direction so as to overlap the first bonding region; an adhesive layer applied between the second chip and the substrate; a plurality of second bonding wires with one end thereof bonded to the active surface of the second chip and the other end thereof bonded to a second bonding region on the substrate; and an encapsulant formed on the substrate for encapsulating the first chip, the first bonding wires, the adhesive layer, the second chip and the second bonding wires.

The adhesive layer is made up of an insulating adhesive material. The adhesive layer may further comprise a plurality of suspending particles or a plurality of bumps. The suspending particles may be made up of a one selected from the group comprising an insulating polymer material, copper, aluminum, copper tungsten alloy, aluminum alloy, silicon carbon compound and silicon material. The bumps may be solder bumps or stud bumps. In addition, the adhesive layer may further be made up of a tape, which may be a polyimide tape.

The invention also discloses a method for fabricating a multi-chip semiconductor package, the method comprises the steps of: providing a substrate and mounting a first chip to the substrate; electrically connecting the first chip to the first bonding region of the substrate through a plurality of first bonding wires; mounting a second chip onto the substrate at a position proximate to the first chip in a horizontal direction and applying an adhesive layer between the second chip and the substrate, allowing the adhesive layer to cover the first bonding region and a portion of a wireloop of each of the first bonding wires; electrically connecting the second chip to a second bonding region of the substrate through a plurality of second bonding wires; and performing a molding process to form an encapsulant completely encapsulating the first chip, the first bonding wires, the adhesive layer, the second chip and the second bonding wires on the substrate.

The invention further discloses a method for fabricating a semiconductor package, the method comprises the steps of: providing a substrate and mounting a first chip to the substrate; electrically connecting the first chip to a first bonding region of the substrate through a plurality of first bonding wires; applying an adhesive on the substrate at a position proximate to the first chip in a horizontal direction to form an adhesive layer, allowing the adhesive layer to cover the first bonding region and a portion of a wireloop of each of the first bonding wires; mounting a second chip on the adhesive layer electrically connecting the second chip to a second bonding region of the substrate through a plurality of second bonding wires; and performing a molding process to form an encapsulant completely encapsulating the first chip, the first bonding wires, the adhesive layer, the second chip and the second bonding wires on the substrate.

The adhesive layer is an insulating, gel-like substance, and the gel-like substance is made up of one selected from the group consisting of at least an epoxy resin and a polyimide material. The adhesive layer may further includes one of a plurality of suspended particles or a plurality of bumps, and the suspended particles is made up of one selected from the group consisting of an insulating, high-molecular, polymeric material, copper, aluminum, copper-tungsten alloy, aluminum alloy, carbon/silicon and silicon. The bumps may be made from conductive or non-conductive, high-molecular, polymeric materials.

The invention still discloses a method for fabricating a semiconductor package, comprising the steps of: providing a substrate and mounting a first chip to the substrate; electrically connecting the first chip to a first bonding region of the substrate through a plurality of first bonding wires; mounting a tape to the substrate at a position proximate to the first chip in a horizontal direction; mounting a second chip to the tape; electrically connecting the second chip to a second bonding region of the substrate through a plurality of second bonding wires; and performing a molding process to form an encapsulant completely encapsulating the first chip, the first bonding wires, the adhesive layer, the second chip and the second bonding wires on the substrate. Preferably, the tape may be made be a polyimide tape.

In the multi-chip semiconductor package and the method for fabricating the same, of the invention, the substrate may be a ball-grid array (BGA) substrate with a plurality of solder balls mounted onto the bottom S/M layer thereof to serve as external electrical contacts for electrically connecting to an external device. Alternatively, the substrate may be a land-grid array (LGA) substrate with a plurality of metallic connecting points formed on the bottom S/M layer of the substrate to serve as external electrical contacts for electrically connecting to an external device.

It should be noted that selections of the substrate employed in the multi-chip semiconductor of the invention can be modified and reconfigured, in the premise that the spirit and the scope of the invention are not violated.

Accordingly, in the multi-chip semiconductor package and a method for fabricating the same, of the invention, chips are mounted onto the substrate, such that they are horizontally spaced from each other. This avoids the problems of increased thickness of the semiconductor package caused by stacking, as occurring in the prior art. Moreover, the semiconductor package and a method for fabricating the same directly mount the second chip onto the substrate though the insulating adhesive layer, and therefore, there is no need to clear out the first bonding region. This reduces space wasted on substrates, and subsequently allowing containing of more or larger-sized chips

Furthermore, adding solid materials can lower fluidity of the adhesive used in the invention so that the second chip could maintain more planeness after being soldered to the adhesive layer. This avoids the problem of chip sliding or overlow of adhesives, and improves yields of products.

### BRIEF DESCRIPTION OF DRAWINGS

The invention can be more fully understood by reading the following detailed description of the preferred embodiments, with reference to the accompanying drawings, wherein:

FIG. 1 is a schematic cross-sectional view showing semiconductor package with multiple chips spaced from each other, in the prior art;

FIG. 2 is a schematic cross-sectional view showing a semiconductor package with multiple stacked chips disclosed in US Patent No.5,793,108;

FIG. 3 is a schematic cross-sectional view showing a multi-chip semiconductor package disclosed by US Patent No. 6,900,528;

FIGS. 4A and 4B are schematic cross-sectional views showing a multi-chip semiconductor package according to a first embodiment of the present invention;

FIGS. 5A to 5F are schematic cross-sectional views showing a method for fabricating a multi-chip semiconductor package according to a first embodiment of the present invention;

FIGS. 6A and 6B are schematic cross-sectional views showing a multi-chip semiconductor package and a method for fabricating the same according to a second embodiment of the present invention;

FIGS. 7A and 7B are schematic cross-sectional views showing a multi-chip semiconductor package and a method for fabricating the same according to a third embodiment of the present invention;

FIGS. 8A and 8B are schematic cross-sectional views showing a multi-chip semiconductor package and a method for fabricating the same according to a fourth embodiment of the present invention; and

FIGS. 9A and 9B are schematic cross-sectional views showing a multi-chip semiconductor package and a method for fabricating the same according to a fifth embodiment of the present invention.

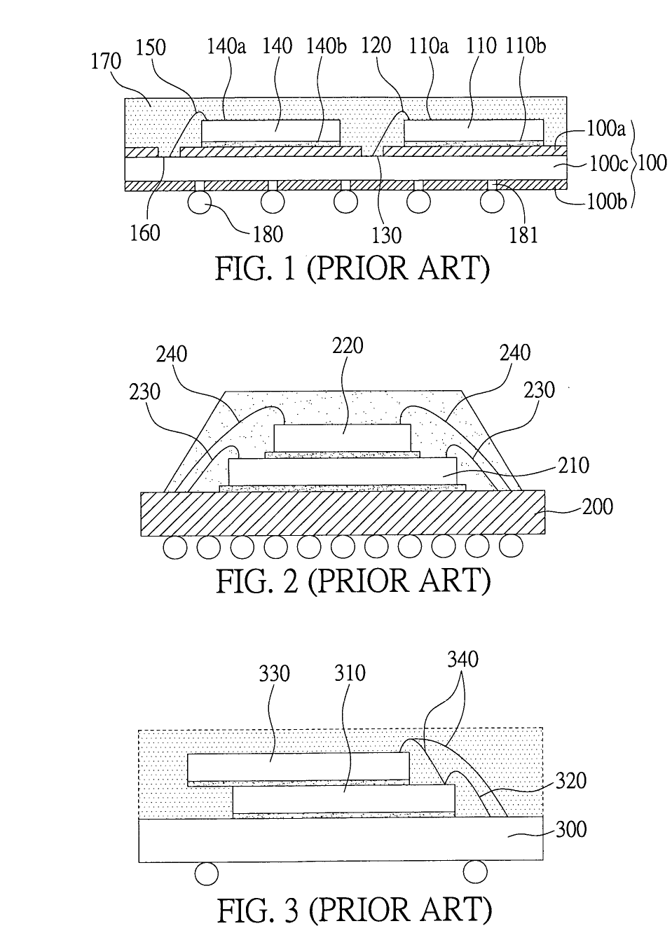

### DETAILED DESCRIPTION OF PREFERRED EMBODIMENTS

The embodiments below further illustrate the means according to the present invention, but are not limiting the scope of the present invention.

### First Embodiment

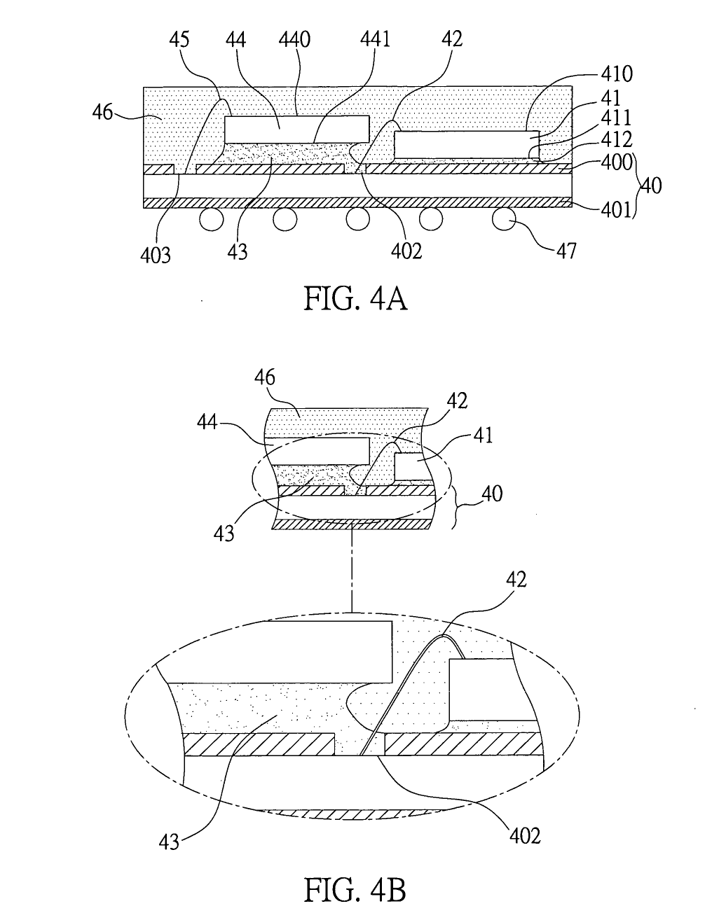

Referring to FIGS. 4A and 4B, FIGS. 4A and 4B are schematic diagrams of a multi-chip semiconductor package fabricated according to a first embodiment of the present invention. As shown in FIGS. 4A and 4B, the multi-chip semiconductor package comprising: a substrate 40; a first chip 41 mounted onto the substrate 40; and a plurality of first bonding wires 42 for electrically connecting the first chip 41 to the substrate 40; a second chip 44 mounted onto the substrate 40 at a position proximate to the first chip 41 in a horizontal direction; an adhesive layer 43 applied between the second chip 44 and the substrate 40; a plurality of second bonding wires 45 for electrically connecting the second chip 44 to the substrate 40; and an encapsulant 46 for encapsulating the first chip 41, the first bonding wires 42, the adhesive layer 43, the second chip 44 and the second bonding wires 45. The substrate 40 may be a ball-grid array (BGA) substrate or a land-grid array (LGA) substrate. However, as these types of substrates are well known in the art, details of these substrates are thus not described hereinafter. Furthermore, the substrate 40 comprises a top S/M (solder/mask) layer 400 and a bottom S/M layer 401 opposing to the top S/M layer 400, wherein the top S/M layer 400 has a plurality of predetermined chip-mounting regions (not shown) and a plurality of predetermined wire-bonding regions (such as the first bonding region 402 and the second bonding region 403) defined thereon, and the bottom S/M layer 401 is formed with an array of solder balls 47 or metal contacts (not shown), so as to allow the first chip 41 and the second chip 44 to be electrically connected to an external device through the solder balls 47 or metal contacts (not shown), so that the first chip 41 and the second chip 44 mounted onto the substrate 40 can be connected to an external device through the solder balls 47 or metal contacts.

The first chip 41 is mounted onto one of the predetermined chip-mounting regions on the top S/M layer 400 of the substrate 40 via silver paste 412. In another embodiment, the silver paste 412 is a polyimide tape. The first chip 41 has an active surface 410 and a non-active surface 411, wherein a plurality of bond pads (not shown) are formed on one side or both sides of the active surface 410 of the first chip 41, or on the periphery of the active surface 410. Once the first chip 41 is mounted onto the substrate 40 by a die bonding process, the first bonding wires 42 are employed for coupling with the internal circuits of the first chip 41 through the bond pads (not shown) and bonding to the first bonding region 402, so as to electrically connect the first chip 41 to the substrate 40.

After the wire bonding process of the first bonding wires 42 is completed, the second chip 44 is mounted onto one of the predetermined chip-mounting regions on the top S/M layer 400 via the adhesive layer 43. The second chip 44 is disposed at a position proximate to the first chip 41 in a horizontal position, wherein, the second chip 44 overlap the first bonding region 402. The adhesive layer 43 may be made up of an insulating, gel-like substance such as an epoxy resin or a polyimide material.

The second chip 44 comprises an active surface 440 and a non-active surface 441, wherein a plurality of bond pads (not shown) are be formed on one side or both sides of the active surface 440 of the second chip 44. Once the second chip 44 is mounted onto the substrate 40, the second bonding wires 45 are employed for coupling with the internal circuits of the second chip 44 through the bond pads (not shown) and bonding to the second bonding region 403, so as to electrically connect the second chip 44 to the substrate 40. Because the second chip 44 overlaps the first bonding region 402, less space of the substrate 40 is required for attaching and electrically connecting the chips and allows for more selections in the types and sizes of chips used.

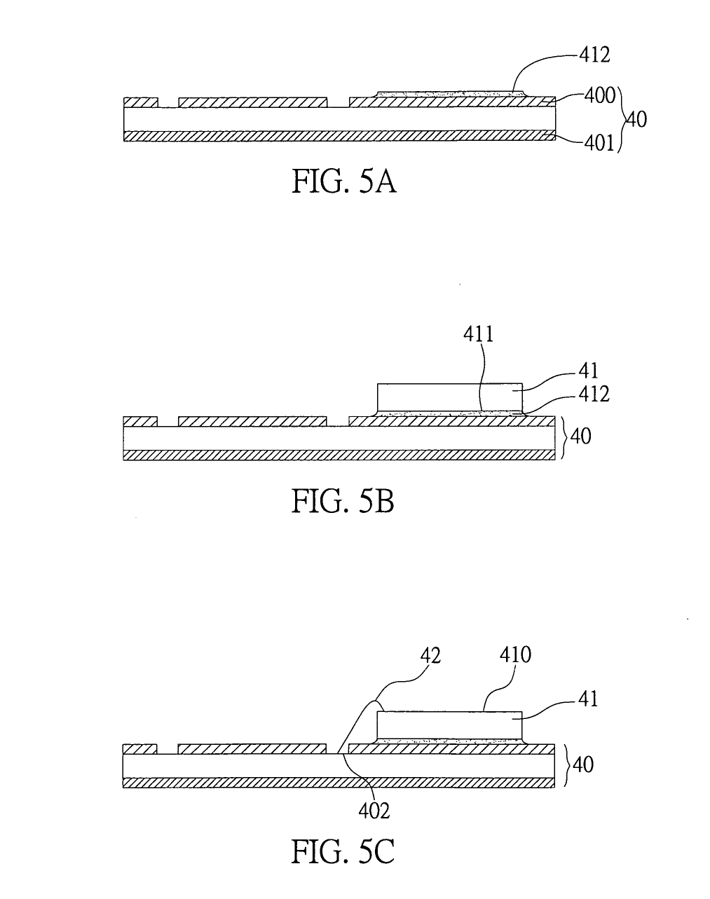

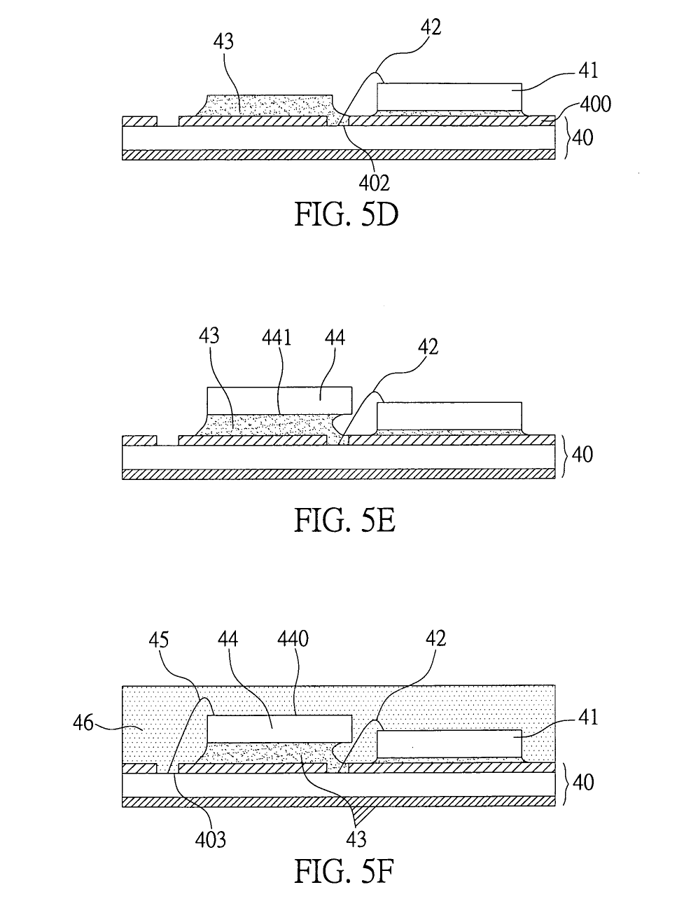

Referring to FIGS. 5A to 5F, FIGS. 5A to 5F are schematic diagrams showing a method for fabricating a multi-chip semiconductor package according to the invention. First, a substrate 40 having a top S/M layer 400 and a bottom S/M layer 401 opposed to the top S/M layer 400 is provided, wherein the top S/M layer 400 is formed with a predetermined chip-mounting region (not shown). Then, the non-active surface 411 of the first chip 41 is mounted onto the chip-mounting region by applying silver paste 412 onto the chip-mounting region by means of a dispensing technique.

As shown in FIG. 5C, the first chip 41 is electrically connected to the substrate 40 by performing a known wire bonding process. The wire bonding process is performed after a die bond curing process, which, by means of a wire-bonder (not shown), melts and bonds an end of the first bonding wire 42 to the bond pads (not shown) of the active surface 410 of the first chip 41, and then bond the other end of the first bonding wires 42 to the first bonding region 402 of the substrate 40.

As shown in FIG. 5D, an adhesive is applied on a predetermined region (not shown) on the top S/M layer 400 of the substrate 40 at one side of the first chip 41 to form the adhesive layer 43, wherein the adhesive layer 43 covers the first bonding region 402 and a portion of a wireloop of each of the first bonding wires 42.

As shown in FIG. 5E, the second chip 44 is mounted onto the adhesive layer 43 through the non-active surface 441 thereof.

As shown in FIG. 5F, the second chip 44 is electrically connected to the substrate 40 by the same wire bonding process previously described. That is, the active surface 440 of the second chip 44 is bonded to the second bonding region 403 on the substrate 40 through the second bonding wires 45, so that the second chip 44 is electrically connected to the substrate 40. After the second bonding wires 45 are bonded, the first chip 41, the adhesive layer 43, the second chip 44 and the substrate 40 are disposed in a packaging mold (not shown) for molding process, to form an encapsulant 46 for encapsulating the first chip 41, the first bonding wires 42, the adhesive layer 43, the second chip 44, and the second bonding wires 45 by means of packaging resins.

### Second Embodiment

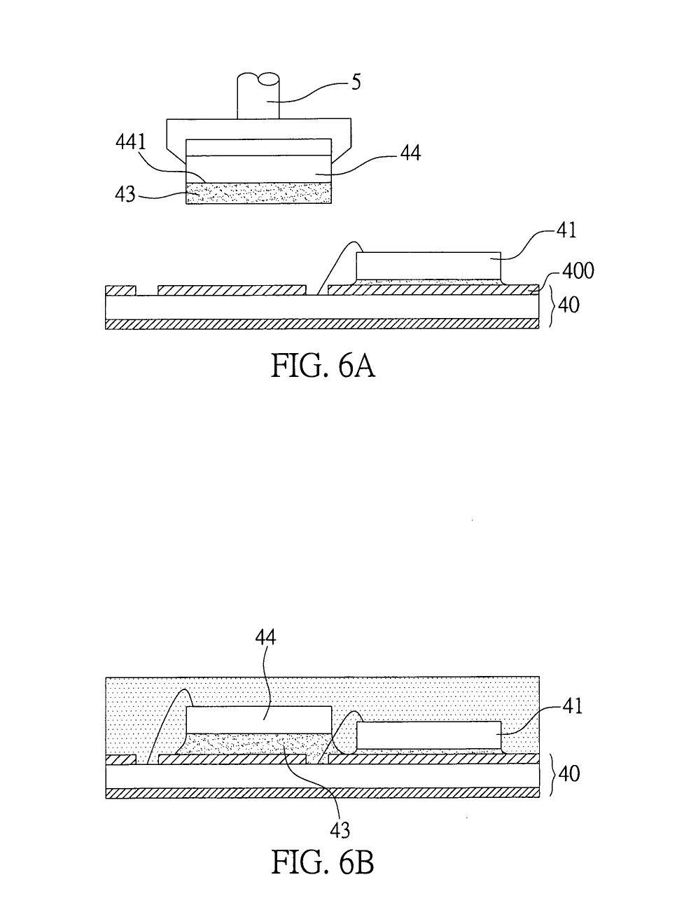

Referring to FIGS. 6A and 6B, FIGS. 6A and 6B are schematic cross-sectional views showing a multi-chip semiconductor package and a method for fabricating the same according to a second embodiment of the invention. One of the major differences from the first embodiment is that a Wafer Back Laminate (WBL) technique is employed for mounting the second chip 44 onto the substrate 40. First, an adhesive 43 is coated onto the non-active surface 441 of the second chip 44 to form the adhesive layer 43. Subsequently, a pick-up head 5 is employed to fasten the second chip 44 and the adhesive layer 43. Next, the adhesive layer 43 is melted and turned into the molten state by heat delivered from the pick-up head, and then the adhesive layer 43 is directly pressed against the predetermined region (not shown) on the top S/M layer 400 of the substrate 40 at one side of the first chip 41, wherein the adhesive layer 43 completely overlap the first bonding region 402 and a portion of a wireloop of each of the first bonding wires 42 to simplify the steps and increase efficiency.

### Third Embodiment

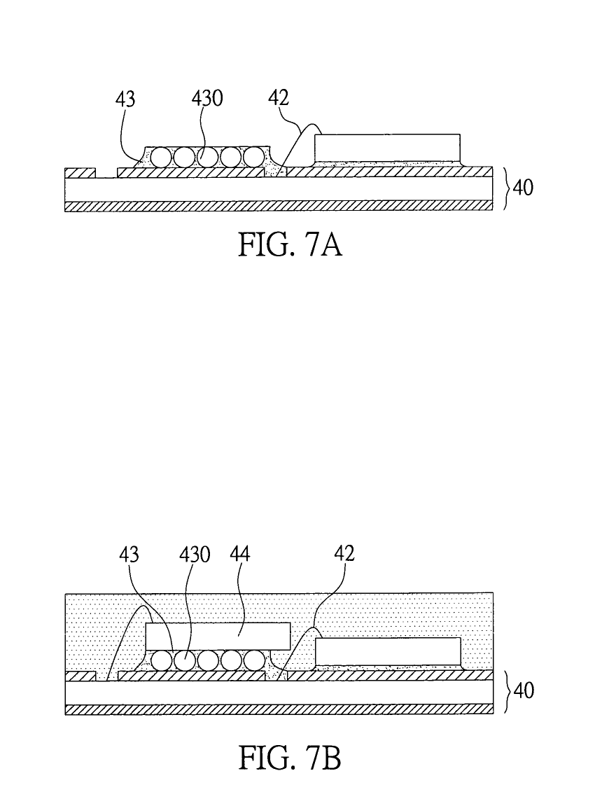

Referring to FIGS. 7A and 7B, FIGS. 7A and 7B are schematic diagrams showing a multi-chip semiconductor package and a method for fabricating the same according to a third embodiment of the present invention. One of the major differences between this embodiment and the first embodiment is that the adhesive 43 is made up of a gel-like substance evenly mixed with a plurality of suspending particles 430.

The suspending particles 430 are made up of an insulating, high-molecular polymeric material, metallic material (such as copper (Cu), aluminum (Al), copper tungsten alloys (e.g., CuW), aluminum alloys (e.g., AIN) or other materials with good rigidity (such as carbon/silicon or silicon particles). However, after the particles 430 are ground into predetermined sizes, surfaces of the particles 430 may be covered with an insulating film (not shown), in order to prevent the suspending particles 430 with good electrical conductivity from contacting with the bonding wires or chips to cause improper electrical connections therebetween.

### Fourth Embodiment

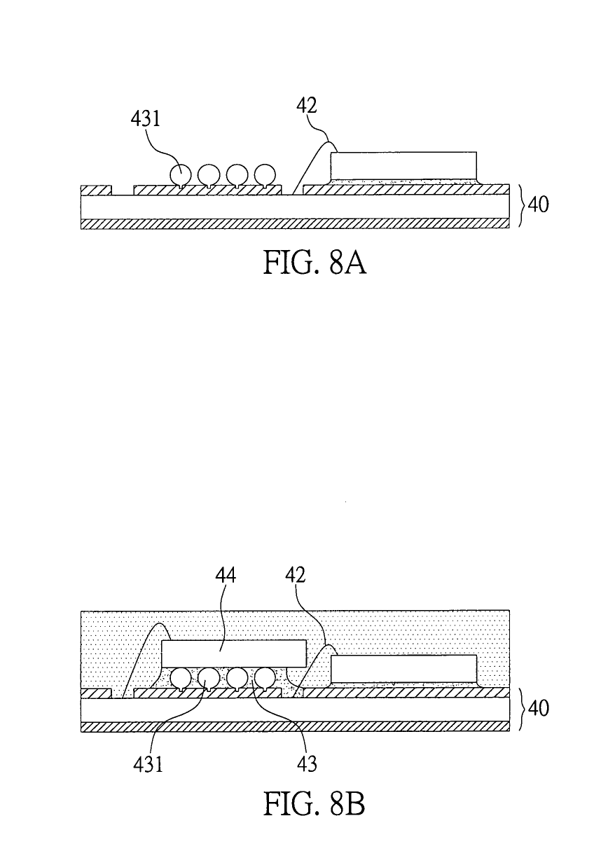

Referring to FIGS. 8A and 8B, FIGS. 8A and 8B are schematic diagrams showing a multi-chip semiconductor package and a method for fabricating the same according to a fourth embodiment of the present invention. One of the major differences between this embodiment and the first embodiment is that, before applying the adhesive 43 onto the substrate 40, a plurality of bumps 431 are disposed at predetermined regions (not shown) on the substrate 40. Subsequently, the adhesive 43 is coated onto the substrate 40 to form an adhesive layer 43 for mounting the second chip 44, wherein the bumps 431 may be solder bumps or stud bumps.

### Fifth Embodiment

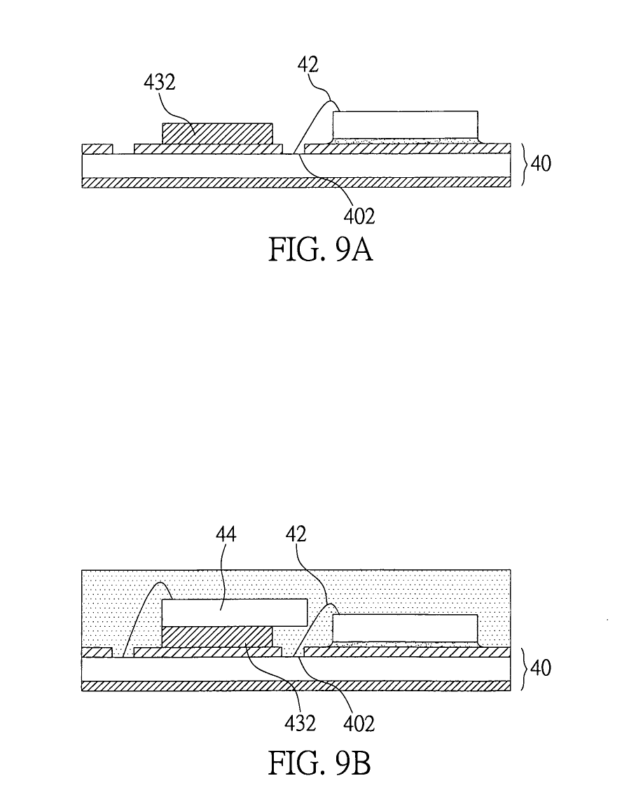

Referring to FIGS. 9A and 9B, FIGS. 9A and 9B are schematic diagrams showing a multi-chip semiconductor package and a method for fabricating the same according to a fifth embodiment of the present invention. One of the major differences between this embodiment and the first embodiment is that the adhesive layer is a tape 432, and the tape 432 does not cover the first bonding region 402 and the first bonding wires 42, wherein the tape 432 is made up of an insulative, high-molecular polymeric material (which may be a polyimide tape). Then, the second chip 44 is attached onto the tape 432, and overlaps with the first bonding region 402.

It should be noted that different types of adhesive materials or different forms/applications of adhesive layers may be employed in each of the above-mentioned embodiments, and shall not be limited to what has been described herein.

Accordingly, chips are mounted onto the substrate are separated horizontally from each other by the method of fabricating in the multi-chip semiconductor chip of the invention, to solve the problem of an overall increased height after packaging by a stacking approach is completed in the prior art, to follow the trend of miniaturization of electronic products. The multi-chip semiconductor package and a method for fabricating the same, of the invention, overlaps the second chip with the first bonding region to reduce the space wasted on the substrate, without separating each of the bonding regions. Therefore, more or larger-sized chips can be integrated, and in turn, increases the ability and capacity of the package. As a result, the problems of chip sliding or overflow of adhesive are avoided, and yields of products are increased. It is known from above that the multi-chip semiconductor package and a method for fabricating the same, of the invention, solve many drawbacks in the prior art, while having values for industrial applicability.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A multi-chip semiconductor package, comprising:
a substrate;
a first chip having an active surface and a non-active surface opposed to the active surface, the first chip being mounted onto the substrate through its non-active surface;
a plurality of first bonding wires with one end thereof bonded onto the active surface of the first chip and the other end bonded onto a first bonding region on the substrate;
at least a second chip having an active surface and a non-active surface opposed to the active surface, wherein the second chip is mounted to the substrate at a position proximate to the first chip in a horizontal direction so as to overlap the first bonding region;
an adhesive layer applied between the second chip and the substrate;
a plurality of second bonding wires with one end thereof bonded onto the active surface of the second chip and the other end thereof bonded onto a second bonding region on the substrate; and
an encapsulant formed on the substrate for encapsulating the first chip, the first bonding wires, the adhesive layer, the second chip and the second bonding wires.

2. The multi-chip semiconductor package of claim 1, wherein the adhesive layer is made up of an insulating, gel-like substance.

3. The multi-chip semiconductor package of claim 2, wherein the gel-like substance is one selected from the group consisting of an epoxy resin and a polyimide material.

4. The multi-chip semiconductor package of claim 1, wherein the adhesive layer further comprises a plurality of suspending particles or a plurality of bumps.

5. The multi-chip semiconductor package of claim 4, wherein the suspending particles are made up of a one selected from the group consisting of an insulating, high-molecular polymeric material, copper, aluminum, copper tungsten alloy, aluminum alloy, silicon carbon compound and silicon.

6. The multi-chip semiconductor package of claim 4, wherein each of the bumps is one of a solder bump and a stud bump.

7. The multi-chip semiconductor package of claim 1, wherein the adhesive layer is a tape.

8. The multi-chip semiconductor package of claim 7, wherein the tape is a polyimide tape.

9. A fabricating method of a multi-chip semiconductor package, comprising the steps of:
providing a substrate and mounting a first chip onto the substrate;
electrically connecting the first chip to a first bonding region on the substrate through a plurality of first bonding wires;
mounting a second chip onto the substrate at a position proximate to the first chip in a horizontal direction, and applying an adhesive layer between the second chip and the substrate, wherein the adhesive layer covers the first bonding region and a portion of wireloop of each of the first bonding wires;
electrically connecting the second chip to a second bonding region on the substrate through a plurality of second bonding wires; and
performing a molding process to form an encapsulant completely encapsulating the first chip, the first bonding wires, the adhesive layer, the second chip and the second bonding wires on the substrate.

10. The fabricating method of claim 9, wherein the adhesive layer is made up of an insulating, gel-like substance.

11. The fabricating method of claim 10, wherein the gel-like substance is made up of one selected from the group consisting of an epoxy resin and a polyimide material.

12. A fabricating method of a multi-chip semiconductor package, comprising the steps of:
providing a substrate and mounting a first chip onto the substrate;
electrically connecting the first chip to a first bonding region on the substrate through a plurality of first bonding wires;
coating an adhesive on the substrate at a position proximate to the first chip in a horizontal direction, wherein the adhesive covers the first bonding region and a portion of a wireloop of each of the first bonding wires, to form an adhesive layer;
mounting a second chip onto the adhesive layer;
electrically connecting the second chip to a second bonding region on the substrate through a plurality of second bonding wires; and
performing a molding process to form an encapsulant for encapsulating the first chip, the first bonding wires, the adhesive layer, the second chip and the second bonding wires on the substrate.

13. The fabricating method of claim 12, wherein the adhesive layer is made up of an insulating, gel-like substance.

14. The fabricating method of claim 13, wherein the adhesive material is made up of one selected from the group consisting of an epoxy resin and a polyimide material.

15. The fabricating method of claim 12, wherein the adhesive layer further comprises one selected from the group consisting of a plurality of suspending particles and a plurality of bumps.

16. The fabricating method of claim 15, wherein the suspending particles are made up of one selected from the group consisting of an insulating, high-molecular polymeric material, copper, aluminum, copper tungsten alloy, aluminum alloy, silicon carbon compound and silicon.

17. The fabricating method of claim 15, wherein each of the bumps is one of a solder bump and a stud bump.

18. A fabricating method of a multi-chip semiconductor package, comprising the steps of:
providing a substrate and mounting a first chip onto the substrate;
electrically connecting the first chip to a first bonding region on the substrate through a plurality of first bonding wires;
mounting a tape onto the substrate at a position proximate to the first chip in a horizontal direction;
mounting a second chip onto the tape, wherein the second chip overlaps the first bonding region;
electrically connecting the second chip to a second bonding region on the substrate through a plurality of second bonding wires; and
performing a molding process to form an encapsulant encapsulating the first chip, the first bonding wires, the adhesive layer, the second chip and the second bonding wires on the substrate.

19. The fabricating method of claim 18, wherein the tape is a polyimide tape.
